(19) United States
(12) Patent Application Publication
(10) Pub. No.: US 2026/0165194 A1
(43) Pub. Date: Jun. 11, 2026

(54) SEMICONDUCTOR PACKAGE INCLUDING DIFFERENT FILLERS

(71) Applicant: Samsung Electronics Co., Ltd., Suwon-si (KR)

(72) Inventors: Seunghwan Baek, Suwon-si (KR); Byungkeun Kang, Suwon-si (KR); Younhwan Shin, Suwon-si (KR); Dongju Jang, Suwon-si (KR)

(21) Appl. No.: 19/402,114

(22) Filed: Nov. 26, 2025

(30) Foreign Application Priority Data
Dec. 9, 2024 (KR) 10-2024-0181270

(51) Int. Cl. H10W 74/47

(52) U.S. Cl. CPC H10W 74/473; H10W 74/121; H10W 90/724

(57) ABSTRACT

A semiconductor package includes a package substrate, a semiconductor chip, a first molding compound and a second molding compound. The semiconductor chip is mounted on the package substrate. The semiconductor chip includes a first surface on which chip pads are formed and a second surface opposite the first surface, and the first surface faces the package substrate. The first molding compound covers sidewalls of the semiconductor chip. The first molding compound includes a first filler having a first thermal conductivity and a first hardness. The second molding compound may contact the second surface of the semiconductor chip, and covers the second surface of the semiconductor chip. The second molding compound contacts a portion of the first molding compound. The second molding compound includes a second filler having a second thermal conductivity different from the first thermal conductivity and a second hardness different from the first hardness.

### CROSS-REFERENCE TO RELATED APPLICATION

This application claims priority under 35 USC § 119 to Korean Patent Application No. 10-2024-0181270, filed on Dec. 9, 2024, in the Korean Intellectual Property Office (KIPO), the contents of which are incorporated by reference herein in their entirety.

### BACKGROUND

During processes for manufacturing a semiconductor package, a semiconductor chip within the semiconductor package may be damaged by heat generated in the semiconductor package. Therefore, the heat generated in the semiconductor package may be quickly dissipated to an outside of the semiconductor package. However, it is not easy to improve the heat dissipation characteristic of the semiconductor package.

### SUMMARY

Various example embodiments relate to a semiconductor package. Particularly, various example embodiments relate to a semiconductor package having excellent heat dissipation characteristics.

According to some example embodiments, a semiconductor package may include a package substrate, a semiconductor chip, a first molding compound and a second molding compound. The semiconductor chip may be mounted on the package substrate. The semiconductor chip may include a first surface and a second surface opposite the first surface, and the first surface may face the package substrate. The first molding compound may cover sidewalls of the semiconductor chip. The second surface of the semiconductor chip may be exposed with respect to the first molding compound. The first molding compound may include a first filler having a first thermal conductivity and a first hardness. The second molding compound may contact the second surface of the semiconductor chip, and may cover the second surface of the semiconductor chip. The second molding compound may contact a portion of the first molding compound. The second molding compound may include a second filler having a second thermal conductivity different from the first thermal conductivity and a second hardness different from the first hardness.

According to some example embodiments, a semiconductor package may include a package substrate, a semiconductor chip, conductive bumps, a first molding compound and a second molding compound. The semiconductor chip may be disposed on the package substrate. The semiconductor chip may include a first surface and a second surface opposite the first surface, and the first surface of the semiconductor chip may face the package substrate. The conductive bumps may be interposed between the package substrate and the semiconductor chip. The first molding compound may be disposed on the package substrate. The second surface of the semiconductor chip may be exposed with respect to the first molding compound, and may cover at least sidewalls of the semiconductor chip. The first molding compound may include a first epoxy molding compound including a first filler. The second molding compound may contact the entire second surface of the semiconductor chip. The second molding compound may include a second epoxy molding compound including a second filler different from the first filler.

According to some example embodiments, a semiconductor package may include a package substrate, a semiconductor chip, a first molding compound and a second molding compound. The semiconductor chip may be mounted on the package substrate. The semiconductor chip may include a first surface on which chip pads are formed and a second surface opposite the first surface, and the first surface of the semiconductor chip may face the package substrate. The first molding compound may fill a gap between the package substrate and the first surface of the semiconductor chip. The first molding compound may cover sidewalls of the semiconductor chip and an upper surface of the package substrate. The second surface of the semiconductor chip may be exposed with respect to the first molding compound. An upper surface of the first molding compound may be spaced farther from the package substrate than the second surface of the semiconductor chip is, and the first molding compound may include a first filler having a first thermal conductivity. The second molding compound may cover the second surface of the semiconductor chip, and may contact the second surface of the semiconductor chip. The second molding compound may include a second filler having a second thermal conductivity greater than the first thermal conductivity.

According to some example embodiments, there is provided method for manufacturing a semiconductor package. The method may include mounting a semiconductor chip on a strip substrate so that a first surface on which chip pads are formed face the strip substrate; forming a first molding compound on the strip substrate to cover a lower portion of the semiconductor chip and sidewalls of the semiconductor chip and expose a second surface opposite the first surface of the semiconductor chip, and the molding compound including a first filler having a first thermal conductivity and a first hardness; and forming a second molding compound on the second surface of the semiconductor chip to cover the second surface of the semiconductor chip, the second molding compound contacting the entire second surface of the semiconductor chip and at least a portion of the first molding compound, and the second molding compound including a second filler having a second thermal conductivity different from the first thermal conductivity and a second hardness different from the first hardness.

In example embodiments, the second thermal conductivity may be greater than the first thermal conductivity, and the second hardness may be greater than the first hardness.

In example embodiments, the first filler may include a silicon-based filler or an aluminum-based filler, and the second filler may include a carbon-based filler.

In example embodiments, an upper surface of the first molding compound may be higher than the second surface of the semiconductor chip. The second molding compound may contact sidewalls of the first molding compound positioned higher than the second surface of the semiconductor chip.

In example embodiments, forming the first molding compound may include: forming a photoresist pattern on the second surface of the semiconductor chip, forming a preliminary first molding compound on the strip substrate to cover the lower portion of the semiconductor chip and the sidewalls of the semiconductor chip and the photoresist pattern, and including the first filler; planarizing the preliminary first molding compound until the upper surface of the photoresist pattern may be exposed to form the first molding compound; and removing the photoresist pattern.

In addition, forming the second molding compound may include: forming a preliminary second molding compound including the second filler on the upper surface of the first molding compound and the second surface of the semiconductor chip, and planarizing the preliminary second molding compound until the upper surface of the first molding compound may be exposed.

In example embodiments, the upper surface of the first molding compound and the second surface of the semiconductor chip may be coplanar with each other, and the second molding compound may contact the upper surface of the first molding compound.

In example embodiments, the first molding compound and the strip substrate may be cut by a sawing process.

In example embodiments, forming the first molding compound may include: forming a preliminary first molding compound on the package substrate to cover a lower portion of the semiconductor chip and sidewalls and second surface of the semiconductor chip, and the preliminary first molding compound including the first filler; and planarizing the preliminary first molding compound until the second surface of the semiconductor chip may be exposed.

In addition, the second molding compound may be formed on the upper surface of the first molding compound and the second surface of the semiconductor chip.

In example embodiments, the first molding compound, the second molding compound, and the strip substrate may be cut by a sawing process.

In example embodiments, the conductive bumps may be interposed between the strip substrate and the semiconductor chip.

According to example embodiments, in a semiconductor package, heat generated from the semiconductor chip may be quickly discharged through the second molding compound. In addition, during a sawing process for forming the semiconductor package, at least the first molding compound may be sawed, so that defects or harmful effects during the sawing process may be reduced.

However, the effects of the present invention are not limited to the effects described above, and other advantages may be realized within the scope of the spirit and scope of the present invention.

### BRIEF DESCRIPTION OF THE DRAWINGS

Various example embodiments will be more clearly understood from the following detailed description taken in conjunction with the accompanying drawings. FIGS. 1 to 30 represent various non-limiting example embodiments in which:

FIG. 1 is a cross-sectional view illustrating a semiconductor package according to example embodiments;

FIG. 2 is a plan view illustrating a semiconductor package according to example embodiments;

FIG. 3 is an SEM image of a portion P1 of FIG. 1;

FIG. 4 is an SEM image of a portion P2 of FIG. 1;

FIGS. 5 to 20 are cross-sectional views and plan views illustrating a method of manufacturing a semiconductor package according to example embodiments;

FIG. 21 is a cross-sectional view illustrating a semiconductor package according to example embodiments;

FIG. 22 is a plan view illustrating a semiconductor package according to example embodiments; and

FIGS. 23 to 30 are cross-sectional views and plan views illustrating a method of manufacturing a semiconductor package according to example embodiments.

### DETAILED DESCRIPTION

Hereinafter, various example embodiments will be described in detail with reference to the accompanying drawings.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “coplanar,” “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality. The term “substantially” may be used herein to emphasize this meaning.

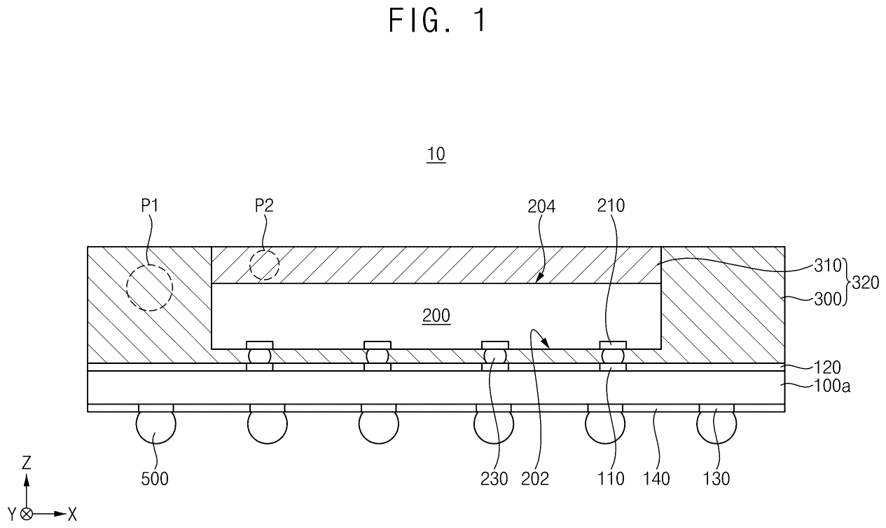

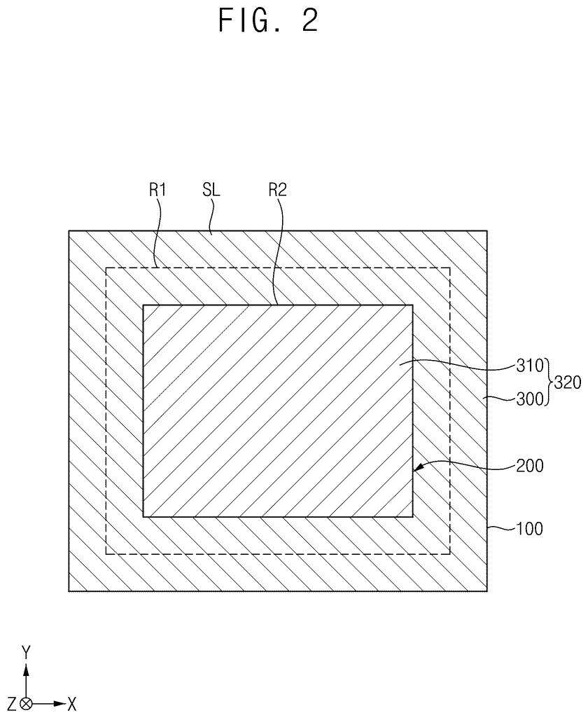

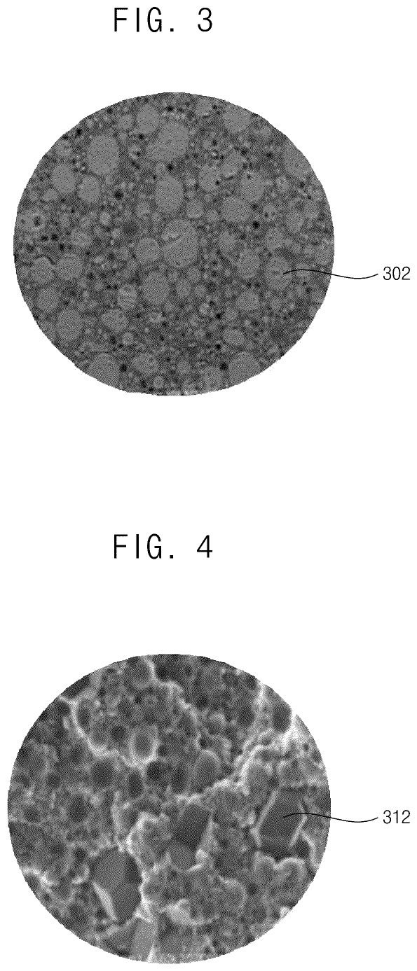

FIG. 1 is a cross-sectional view illustrating a semiconductor package according to example embodiments. FIG. 2 is a plan view illustrating a semiconductor package according to example embodiments. FIG. 3 is an SEM (Scanning Electron Microscope) image of a portion P1 of FIG. 1. FIG. 4 is a SEM image of a portion P2 of FIG. 1.

Referring to FIGS. 1 and 2, a semiconductor package 10 may include a package substrate 100a, a semiconductor chip 200, a first molding member (or molding compound) 300, and a second molding member (or molding compound or molding layer) 310. In addition, the semiconductor package 10 may further include external connection members 500.

The package substrate 100a may be a substrate having upper and lower surfaces facing away from each other. For example, the package substrate 100a may be a printed circuit board (PCB). The printed circuit board may be a multilayer circuit board having vias and various circuits (or wirings) therein. For example, a strip substrate including a plurality of package substrates may be individualized by a sawing process to form the package substrates 100a.

The package substrate 100a may include a plurality of stacked insulation layers and wirings inside each of (or between) the insulation layers. In addition, the package substrate 100a may include a plurality of upper substrate pads 110 and a plurality of lower substrate pads 130. Ones of the wirings may serve as channels for electrical connection with different types of semiconductor chips (or with circuitry external to the semiconductor package 10).

The upper substrate pads 110 may be exposed on (or with respect to) an upper surface of the package substrate 100a. An upper insulation layer 120 may be disposed between the upper substrate pads 110. At least a portion of the upper substrate pads 110 may be exposed by (or with respect to) the upper insulation layer 120. The lower substrate pads 130 may be exposed on a lower surface of the package substrate 100a. The lower insulation layer 140 may be disposed between the lower substrate pads 130. At least a portion of the lower substrate pads 130 may be exposed by the lower insulation layer 140.

In example embodiments, in a plan view, at a center (center region) of the package substrate 100a may include or be a chip region R2 on which chips are disposed. The upper substrate pads 110 may be arranged in the chip region R2 of the package substrate 100a. The upper substrate pads 110 may be arranged in an array form in the chip region R2. In the plan view, the package substrate 100a may have a rectangular shape. In the plan view, the chip region R2 may have a rectangular shape.

The lower substrate pad 130 may be provided to input and output electric signals. The external connection member 500 may be disposed on the lower substrate pad 130 for electrical connection with an external device. For example, the external connection member 500 may be a solder ball. The semiconductor package 10 may be mounted on a module substrate (not shown) using the solder balls to form a memory module.

The semiconductor chip 200 may be mounted on the upper surface of the package substrate 100a. Conductive bumps 230 may be interposed between the package substrate 100a and the semiconductor chip 200. The semiconductor chip 200 may be mounted on the chip region R2 of the package substrate 100a using the conductive bumps 230. The semiconductor chip 200 may have a rectangular shape, in the plan view.

The semiconductor chip 200 may include a substrate including a semiconductor material. The semiconductor chip 200 may include a first surface 202 on which a circuit pattern and chip pads 210 are formed, and a second surface 204 opposite the first surface 202. The first surface 202 of the semiconductor chip 200 may be positioned to face the package substrate 100a. However, the present invention is not limited thereto.

The semiconductor material of the substrate may be exposed on the second surface 204 of the semiconductor chip 200. The circuit pattern and the chip pads may not be formed on the second surface 204 of the semiconductor chip 200. The second surface 204 of the semiconductor chip 200 may be substantially flat.

In example embodiments, the semiconductor chip 200 may be mounted on the package substrate 100a by a flip chip bonding process. The chip pads 210 of the semiconductor chip 200 may be electrically connected to the upper substrate pads 110 of the package substrate 100a via conductive bumps 230. A gap may be formed between the semiconductor chip 200 and the package substrate 100a by interposing the conductive bumps 230. For example, the conductive bumps 230 may include or be micro bumps (uBumps). Each of the conductive bumps 230 may include a conductive pillar serving as a lower bump and a solder serving as an upper bump. The conductive pillar may include, e.g., a copper pillar. The solder may include, e.g., tin Sn, tin/silver Sn/Ag, tin/copper Sn/Cu, tin/indium Sn/In, or tin/silver/copper Sn/Ag/Cu, etc. The conductive bump 230 under the semiconductor chip 200 may be electrically connected to the external connection member 500 through the upper substrate pad 110, the wirings inside the package substrate 100a, and the lower substrate pad 130. Therefore, the semiconductor chip 200 may be electrically connected to the external device by the conductive bump 230.

The first molding member 300 may be disposed on the package substrate 100a to cover sidewalls and a lower surface of the semiconductor chip 200. The first molding member 300 may contact the upper surface of the package substrate 100a. The first molding member 300 may fill a gap between the package substrate 100a and the first surface 202 of the semiconductor chip 200, and may cover the upper surface of the package substrate 100a and the sidewalls of the semiconductor chip 200. An upper surface of a portion of the first molding member 300 contacting the sidewalls of the semiconductor chip 200 may be higher than an upper surface (e.g., a second surface) of the semiconductor chip 200. For example, the upper surface of a portion of the first molding member 300 may be spaced farther from the package substrate 100a than the upper surface of the semiconductor chip 200 is, and the portion of the first molding member 300 may contact the sidewalls of the semiconductor chip 200. A portion of the first molding member 300 may protrude from (or beyond) the second surface 204 of the semiconductor chip 200. In example embodiments, the first molding member 300 may not cover the second surface of the semiconductor chip 200. Therefore, the second surface 204 of the semiconductor chip 200 may be exposed by (or with respect to) the first molding member 300.

The first molding member 300 may include a first filler 302. In example embodiments, the first molding member 300 may be a first epoxy mold compound (EMC) including the first filler 302. The first filler 302 may have a first thermal conductivity and a first hardness.

The strip substrate on which the first molding member 300 is covered may be sawed by the sawing process to form the plurality of package substrates 100a and the first molding member 300 on each of the package substrates 100a, and thus an outer wall of the first molding member 300 and sidewalls of the package substrate 100a in the semiconductor package 10 may defined by the sawing process. Therefore, the outer wall of the first molding member 300 and the sidewalls of the package substrate 100a may extend in a vertical direction (direction Z) without a bent portion. The outer wall of the first molding member 300 and the sidewalls of the package substrate 100a may be aligned on a straight line in the vertical direction(or in a vertical cross sectional view). For example, the outer wall of the first molding member 300 and the sidewalls of the package substrate 100a may be substantially coplanar with (or be flush with or terminate in the same plane as) each other. The first molding member 300 may include a material that can be easily cut by the sawing process.

In example embodiments, the first filler 302 may include a silicon-based filler or an aluminum-based filler. For example, the first filler 302 may include a silica filler or an aluminum oxide filler. When the first filler 302 includes the silica filler, as shown in FIG. 3, the silica filler may have a circular shape of cross-section.

The second molding member 310 may be disposed on the second surface 204 of the semiconductor chip 200. The second molding member 310 may contact the second surface 204 of the semiconductor chip 200, and may cover the second surface of the semiconductor chip 200. In addition, the second molding member 310 may contact an upper sidewalls of the first molding member 300 that is positioned higher than the upper surface of the semiconductor chip 200. For example, the second molding member 310 may contact an upper portion of sidewalls of the first molding member 300, and the upper portion of sidewalls may be spaced farther from the package substrate 100a than the upper surface of the semiconductor chip 200 is. In example embodiments, the first molding member 300 may not be positioned on the second surface 204 of the semiconductor chip 200. A boundary between the first and second molding members 300 and 310 may be distinguished. A boundary surface between the first and second molding members 300 and 310 may extend upward from an edge of the second surface 204 of the semiconductor chip 200. In example embodiments, the boundary surface between the first and second molding member 300 and 310 may be positioned on the second surface 204 of the semiconductor chip 200.

Upper surfaces of the first and second molding members 300 and 310 may be substantially flat. The upper surfaces of the first and second molding members 300 and 310 may be substantially coplanar with each other.

The second molding member 310 may include a second filler 312 that is different from the first filler 302. For example, the second filler 312 may include a material different from the material of the first filler 302. The second molding member 310 may be a second epoxy mold compound (EMC) including the second filler 312. The second filler 312 may have a second thermal conductivity different from the first thermal conductivity and a second hardness different from the first hardness.

The second molding member 310 may contact the second surface 204 of the semiconductor chip 200, a heat generated in the semiconductor chip 200 or a heat applied to the semiconductor chip 200 may be dissipated to an outside of the semiconductor package 10 by the second molding member 310. Therefore, the second filler 312 included in the second molding member 310 may have high thermal conductivity. The second thermal conductivity may be higher (or greater) than the first thermal conductivity, and the second hardness may be higher (or greater) than the first hardness.

In example embodiments, the second filler 312 may include a carbon-based filler. The second filler 312 may include, e.g., a diamond filler. In this case, as shown in FIG. 4, the diamond filler included in the second molding member 310 may have a polygonal shape of cross-section.

When the first filler 302 includes the silica filler, as shown in FIG. 3, the silica filler may have a circular shape of cross-section.

The first filler 302 included in the first molding member 300 and the second filler 312 included in the second molding member 310 may have different shapes of cross-section. Therefore, the first filler 302 included in the first molding member 300 and the second filler 312 included in the second molding member 310 may be easily distinguished by the shapes of cross-section.

In some example embodiments, the second filler 312 may include a metal-based filler. The metal-based filler may be, e.g., a metal particle such as gold, silver (Ag), copper (Cu), or nickel (Ni).

The first and second molding members 300 and 310 may further include resin and additives. Amounts of the resin and additives included in the first and second molding members 300 and 310 may be much smaller than amounts of the first and second fillers 302 and 314 included in the first and second molding members 300 and 310. For example, at least 80% of components included in the first molding member 300 may be the first filler 302, and at least 80% components included in the second molding member 310 may be the second filler 312.

A molding member structure 320 including the first and second molding members 300 and 310 may seal the semiconductor chip 200.

As described above, the first filler 302 included in the first molding member 300 may have the first hardness lower than the second hardness of the second filler 312 included in the second molding member 310, so that the first molding member 300 may have a hardness lower than a hardness of the second molding member 310. Therefore, when the semiconductor package 10 is manufactured, the first molding member 300 may be cut more easily than the second molding member 310 by a sawing process. In addition, the second filler 312 included in the second molding member 310 has a thermal conductivity higher (or greater) than a thermal conductivity of the first filler 302 included in the first molding member, so that the heat generated in the semiconductor chip 200 or the heat applied into the semiconductor chip 200 may be easily dissipated to the outside of the semiconductor package 10 by the second molding member 310. Accordingly, defects of the semiconductor package 10 due to the heat generated from the semiconductor chip may be decreased. In addition, in the manufacturing of the semiconductor package 10, defects in the sawing process of the first molding member 300 and the strip substrate 100 may be decreased.

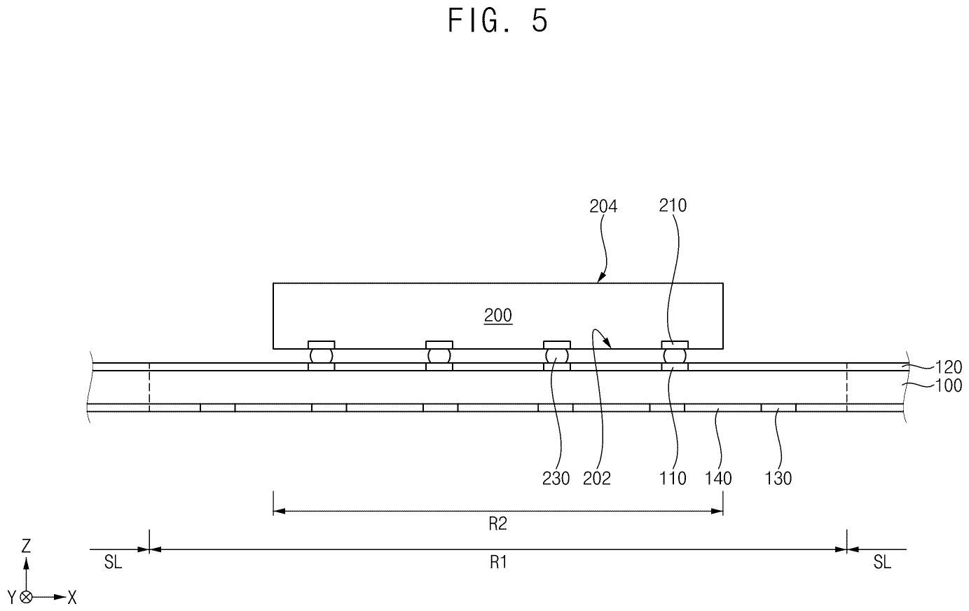

FIGS. 5 to 20 are cross-sectional views and plan views illustrating a method of manufacturing a semiconductor package according to example embodiments.

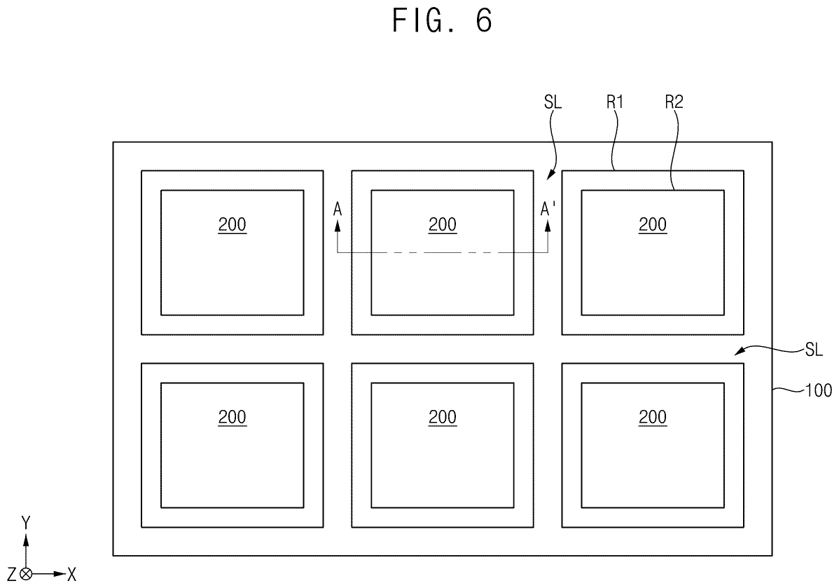

FIGS. 5, 7, 9, 11, 13, 15, 17, and 19 are cross-sectional views illustrating the method for manufacturing the semiconductor package. FIGS. 6, 8, 10, 12, 14, 16, 18, and 20 are plan views illustrating the method for manufacturing the semiconductor package. The cross-sectional views are cut (or taken) along line A-A′ in the respective plan views.

Referring to FIGS. 5 and 6, a strip substrate 100 may be provided. The strip substrate 100 may be a substrate having an upper surface and a lower surface facing away from each other. For example, the strip substrate 100 may be a printed circuit board (PCB) in which circuit patterns and insulation layers are formed on both sides (or opposite sides) of a core layer. The strip substrate 100 may be a rectangular substrate having a first side extending in a first direction X and a second side extending in a second direction Y perpendicular to the first direction X. The strip substrate 100 may include a plurality of package regions R1 and saw lanes SL between the package regions R1, and thus the package regions R1 may be distinguished by the saw lanes SL. In a plan view, a center (center region) of each of the package regions R1 may include or be a chip region R2 on which chips are disposed. In the package region R1, an area between the chip region R2 and the saw lane SL may serve as a peripheral region.

The saw lanes SL may intersect each other in a cross shape to divide the plurality of package regions R1 on the upper surface 102 of the strip substrate 100. The saw lane SL may include a plurality of first scribe lanes extending in the first direction X and a plurality of second scribe lanes extending in the second direction Y.

In example embodiments, the plurality of package regions R1 may be spaced apart from each other to have regular (or predetermined) intervals in the first direction X and the second direction Y. The plurality of package regions R1 may be arranged in an array form on the upper surface of the strip substrate 100. The package regions R1 may have a rectangular shape.

Upper substrate pads 110 may be arranged on an upper portion of the package regions R1, and lower substrate pads 130 may be arranged on a lower portion of the package regions R1. An upper insulation layer 120 may be disposed on sidewalls of the upper substrate pads 110, and a lower insulation layer 140 may be disposed on sidewalls of the lower substrate pads 130. Portions corresponding to the package regions R1 in the strip substrate 100 may be individualized by subsequent processes, so that package substrates may be formed.

Thereafter, a semiconductor chip 200 may be mounted on each of the package regions R1 of the strip substrate 100 by interposing conductive bumps 230.

The semiconductor chip 200 may include a substrate including a semiconductor material. The semiconductor chip 200 may include a first surface 202 on which circuit patterns and chip pads 210 are formed, and a second surface 204 opposite the first surface 202. The first surface 202 of the semiconductor chip 200 may be positioned to face the strip substrate 100.

The semiconductor material may be exposed on the second surface 204 of the semiconductor chip 200. The circuit patterns and the chip pads may not be formed on the second surface 204 of the semiconductor chip 200.

In example embodiments, the semiconductor chip 200 may be mounted on the package region R1 of the strip substrate 100 by a flip chip bonding process. The semiconductor chip 200 may be mounted on the chip region R2 corresponding to the center of the package region R1 in a plan view.

Particularly, the conductive bumps 230 may be formed on the chip pads 210 of the first surface 202 of the semiconductor chip 200, flux may be deposited on surfaces of the conductive bumps 230, and the semiconductor chip 200 may be placed on the chip region R2 of the strip substrate 100. The conductive bumps 230 may be interposed between the upper surface of the chip region R2 of the strip substrate 100 and the first surface 202 of the semiconductor chip 200. The conductive bump 230 may be placed on the upper substrate pad 110 of the chip region R2 of the strip substrate 100. Subsequently, a reflow process may be performed to bond the conductive bump 230 onto the upper substrate pad 110.

For example, the conductive bumps 230 may be formed by a plating process. Alternatively, the conductive bumps 230 may be formed by a screen printing process, a deposition process, or the like. For example, each of the conductive bumps 230 may include a conductive pillar serving as a lower bump and a solder serving as an upper bump. The conductive pillar may include, e.g., a copper pillar. The solder may include, e.g., tin Sn, tin/silver Sn/Ag, tin/copper Sn/Cu, tin/indium Sn/In, or tin/silver/copper Sn/Ag/Cu, etc.

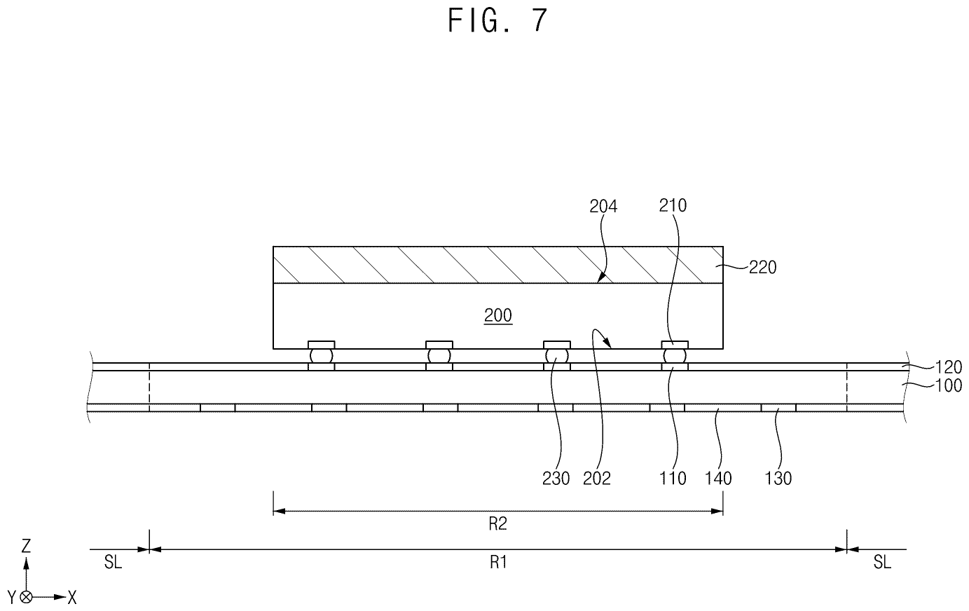

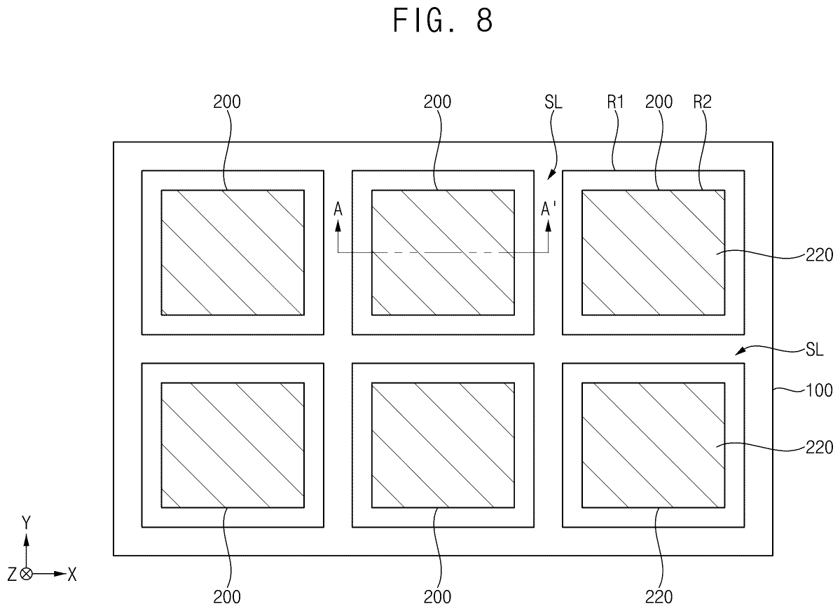

Referring to FIGS. 7 and 8, a photoresist layer may be coated on the strip substrate 100 and patterned to form a photoresist pattern 220 covering the upper surface of the semiconductor chip 200. In example embodiments, the photoresist pattern 220 may cover the entire upper surface of the semiconductor chip 200. The photoresist pattern 220 may not cover the sidewalls of the semiconductor chip 200 and the surface of the strip substrate 100. Therefore, the sidewalls of the semiconductor chip 200 and the surface of the strip substrate 100 may be exposed by the photoresist pattern 220.

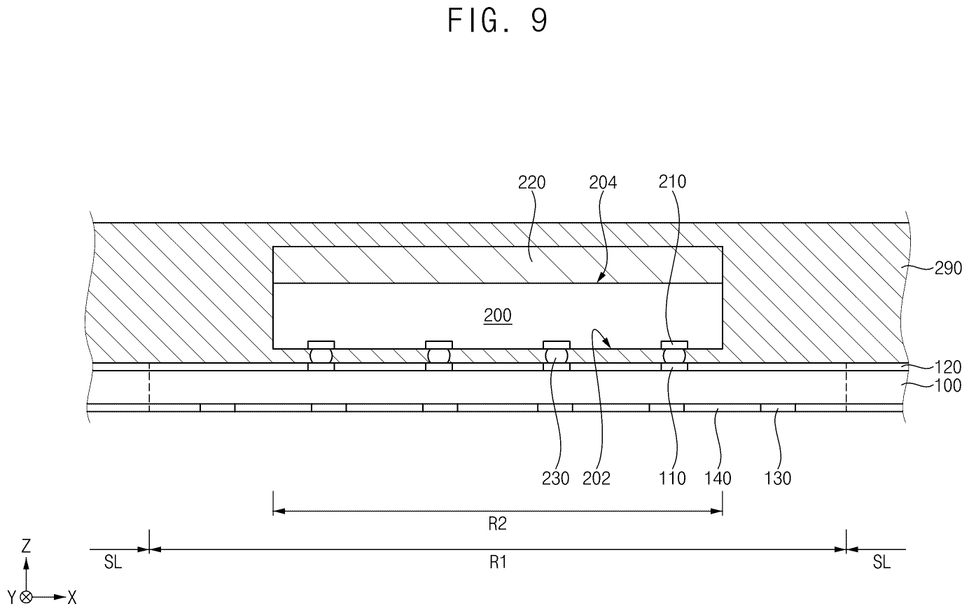

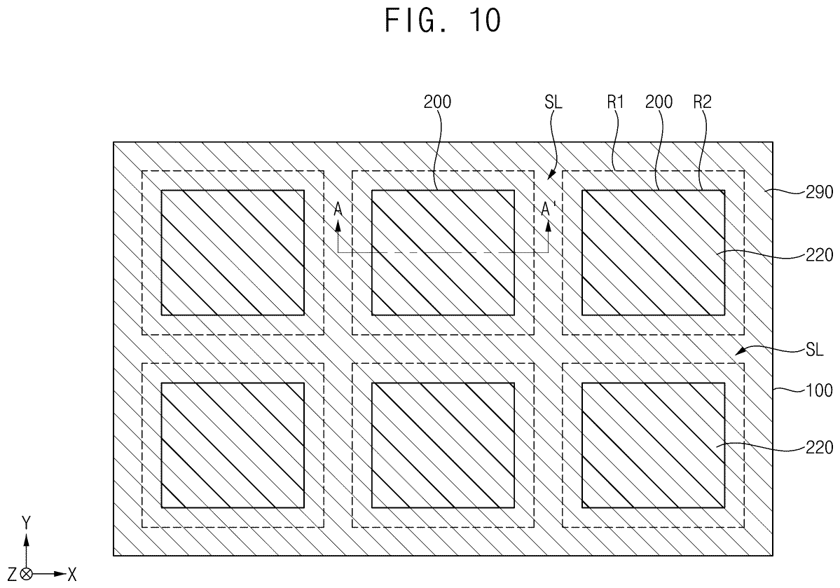

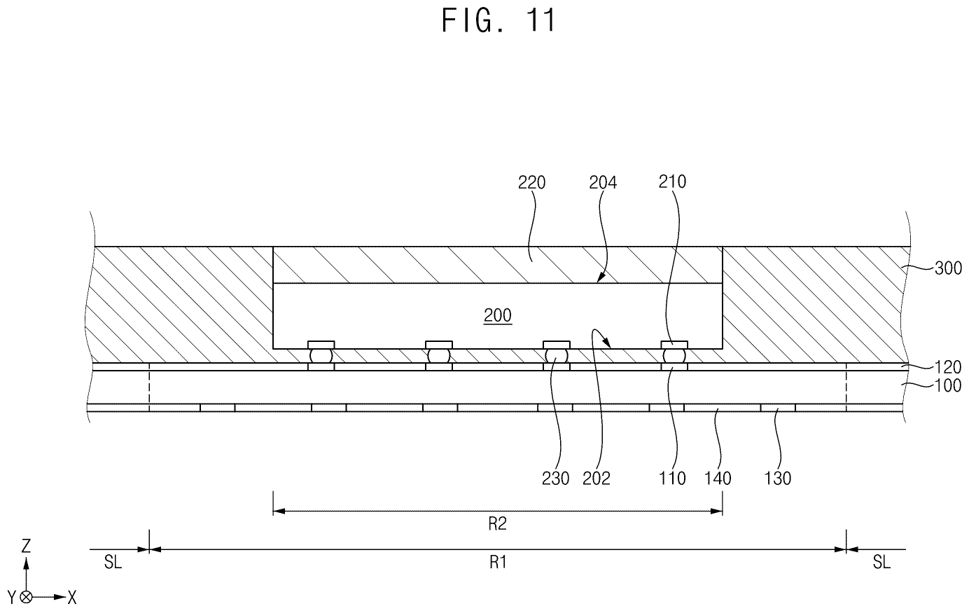

Referring to FIGS. 9 and 10, a preliminary first molding member 290 may be formed on the strip substrate 100 to cover the semiconductor chip 200 and the photoresist pattern 220.

The preliminary first molding member 290 may be an epoxy mold compound (EMC) including a first filler 302. The first filler 302 may have a first thermal conductivity and a first hardness. The preliminary first molding member 290 may include a material that can be easily cut by a sawing process.

In example embodiments, the first filler 302 may include a silicon-based filler or an aluminum-based filler. For example, the first filler 302 may include a silica filler or an aluminum oxide filler. When the first filler 302 is the silica filler, the first filler 302 may have a circular shape of cross-section.

The preliminary first molding member 290 may be formed on the strip substrate 100 to cover the sidewalls and the lower portion of the semiconductor chip 200 and a surface of the photoresist pattern 220. The preliminary first molding member 290 may cover the sidewalls of the semiconductor chip 200 and the photoresist pattern 220, may fill a gap between the strip substrate 100 and the first surface of the semiconductor chip 200, and may cover the upper surface of the photoresist pattern 220. An upper surface of the preliminary first molding member 290 may be higher than the second surface 204 of the semiconductor chip 200. For example, an upper surface of the preliminary first molding member 290 may be spaced farther from the strip substrate 100 than the second surface 204 of the semiconductor chip 200 is.

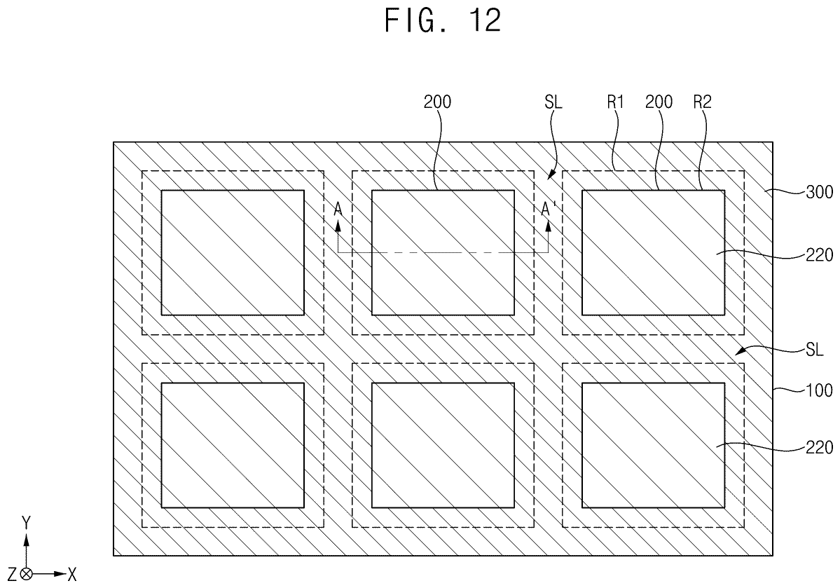

Referring to FIGS. 11 and 12, the upper surface of the preliminary first molding member 290 may be removed by a planarization process until the upper surface of the photoresist pattern 220 may be exposed to form a first molding member 300. For example, the remaining portion of the preliminary first molding member 290 may become a first molding member 300. The planarization process may include or be, e.g., a grinding process.

An upper surface of the first molding member 300 and the upper surface of the photoresist pattern 220 may be substantially coplanar with each other. The upper surface of the first molding member 300 and the upper surface of the photoresist pattern 220 may be substantially flat. The upper surface of the first molding member 300 may be higher than the second surface 204 of the semiconductor chip 200. For example, the upper surface of the first molding member 300 may be spaced farther from the strip substrate 100 than the second surface 204 of the semiconductor chip 200 is.

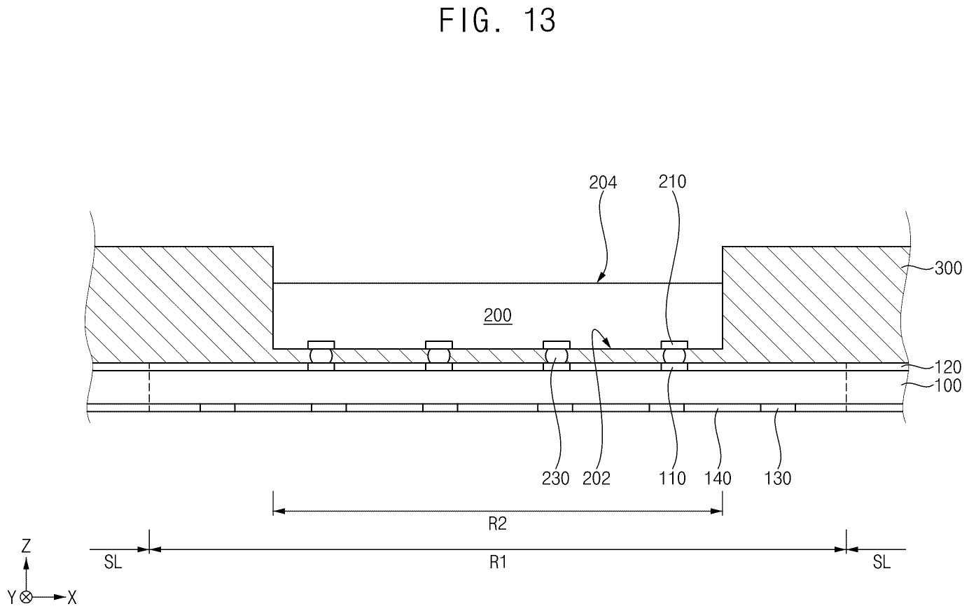

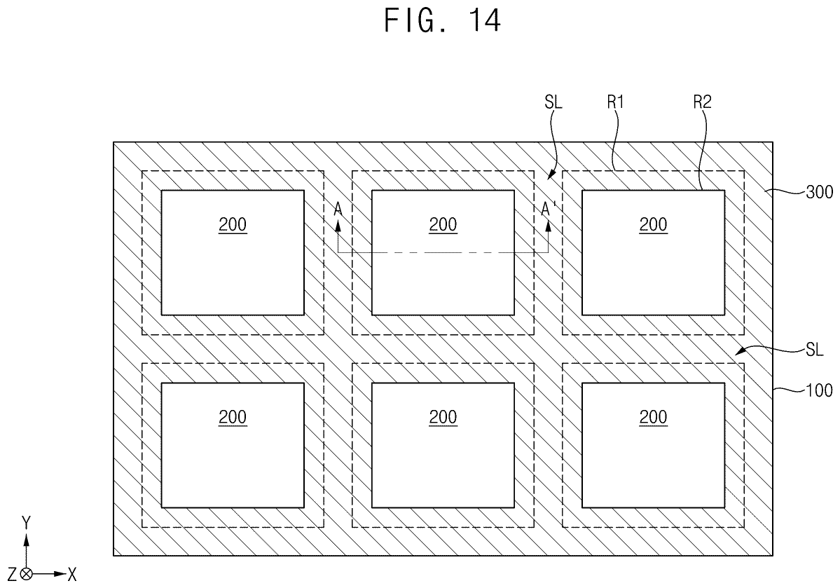

Referring to FIGS. 13 and 14, the photoresist pattern 220 may be removed. Accordingly, a recessed portion may be formed in an area where the photoresist pattern 220 is removed. The second surface 204 of the semiconductor chip 200 and upper sidewalls of the first molding member 300 may be partially exposed by the recessed portion.

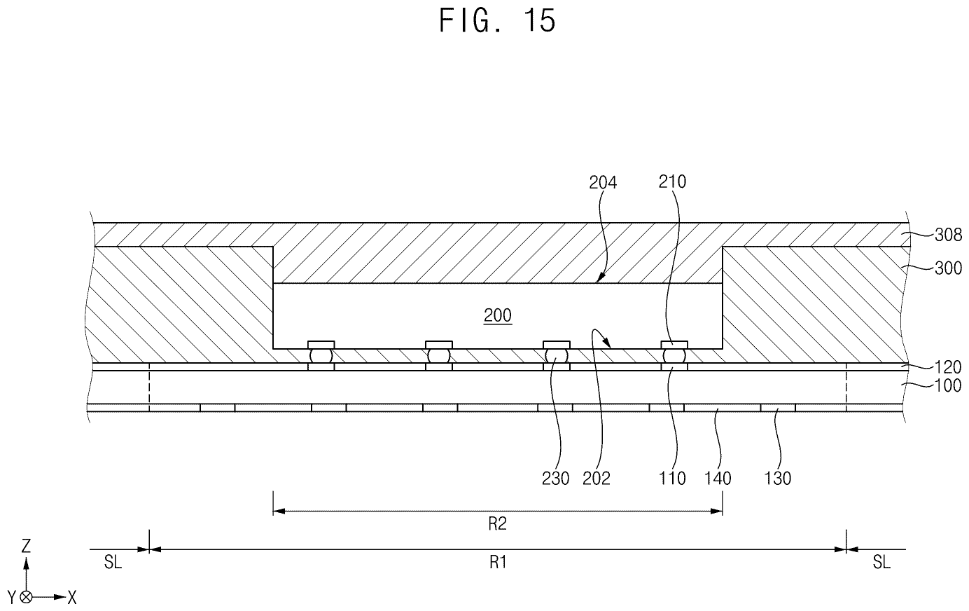

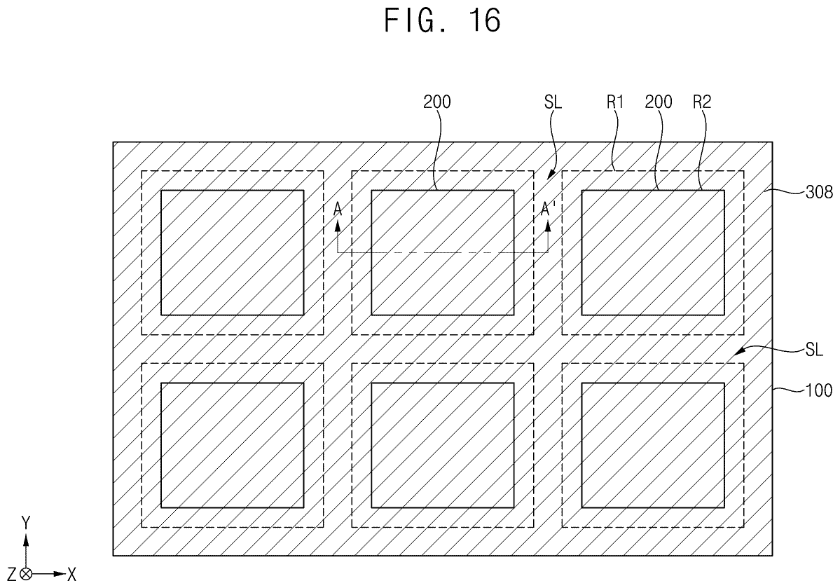

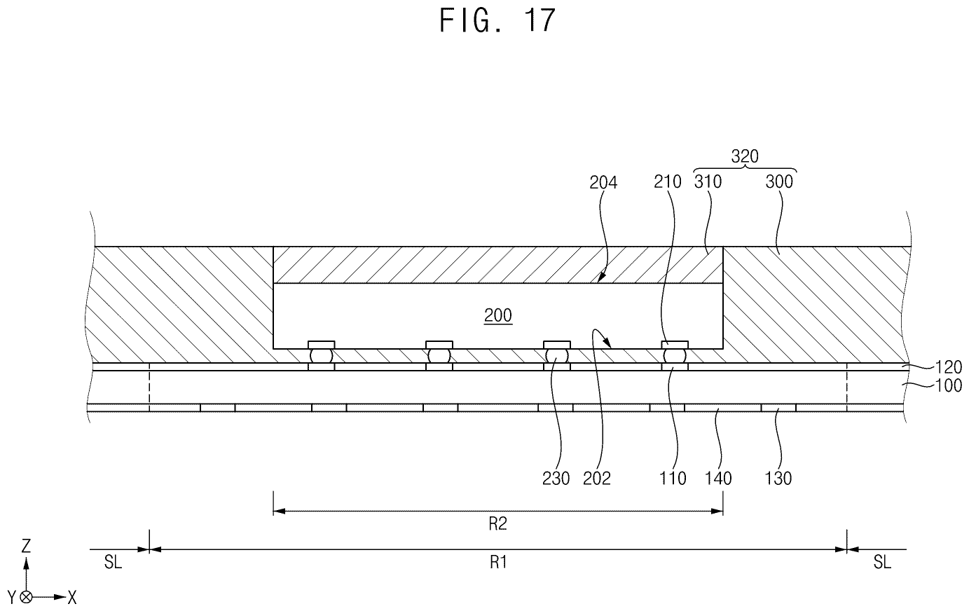

Referring to FIGS. 15 and 16, a preliminary second molding member 308 may be formed on the upper surface and upper sidewalls of the first molding member 300 and the upper surface of the semiconductor chip 200 to fill the recessed portion. The preliminary second molding member 308 may include a second epoxy mold compound (EMC) including a second filler 312 different from the first filler 302. The second filler 312 may have a second thermal conductivity different from the first thermal conductivity and a second hardness different from the first hardness. In example embodiments, the second thermal conductivity may be higher than the first thermal conductivity, and the second hardness may be higher than the first hardness.

In example embodiments, the second filler 312 may include a carbon-based filler. The second filler 312 may include, e.g., a diamond filler, and in this case, the second filler 312 may have a polygonal shape of cross-section.

In some example embodiments, the second filler 312 may include a metal-based filler. The metal-based filler may be, e.g., a metal particle such as gold, silver (Ag), copper (Cu), or nickel (Ni).

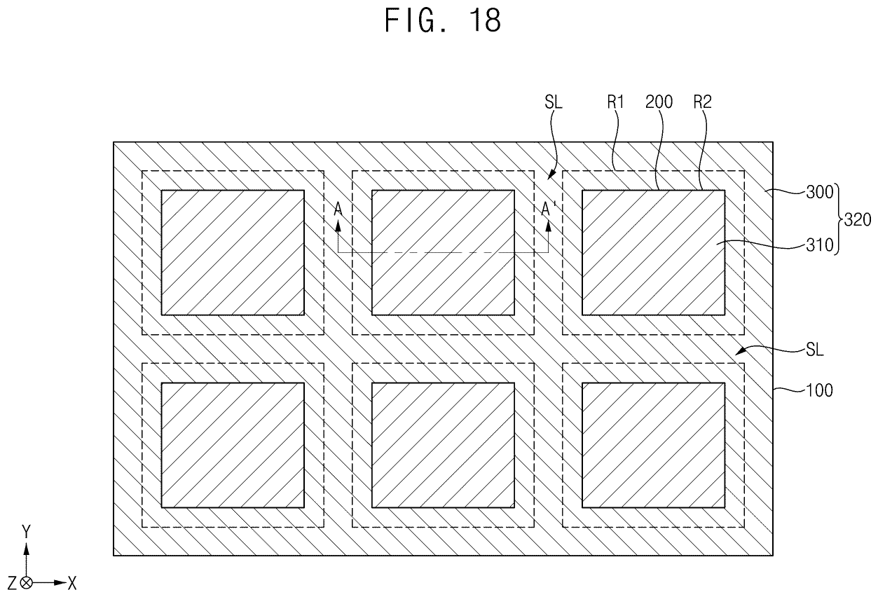

Referring to FIGS. 17 and 18, an upper surface of the preliminary second molding member 308 may be removed by a planarization process until the upper surfaces of the semiconductor chip 200 and the first molding member 300 may be exposed to form a second molding member 310. For example, the remaining portion of the preliminary second molding member 308 may become a second molding member 310. The planarization process may include, e.g., a grinding process. Accordingly, a molding member structure 320 including the first molding member 300 and the second molding member 310 may be formed on the strip substrate 100.

An upper surface of the second molding member 310 and the upper surface of the first molding member 300 may be substantially coplanar with each other. The upper surfaces of the first molding member 300 and the second molding member 310 may be substantially flat. The upper surface of the first molding member 300 may be higher than the second surface 204 of the semiconductor chip 200. For example, the upper surface of the first molding member 300 may be spaced farther from the strip substrate 100 than the second surface 204 of the semiconductor chip 200 is. In example embodiments, the second molding member 310 may not contact the sidewalls of the semiconductor chip 200. A lower surface of the second molding member 310 may contact the second surface 204 of the semiconductor chip 200.

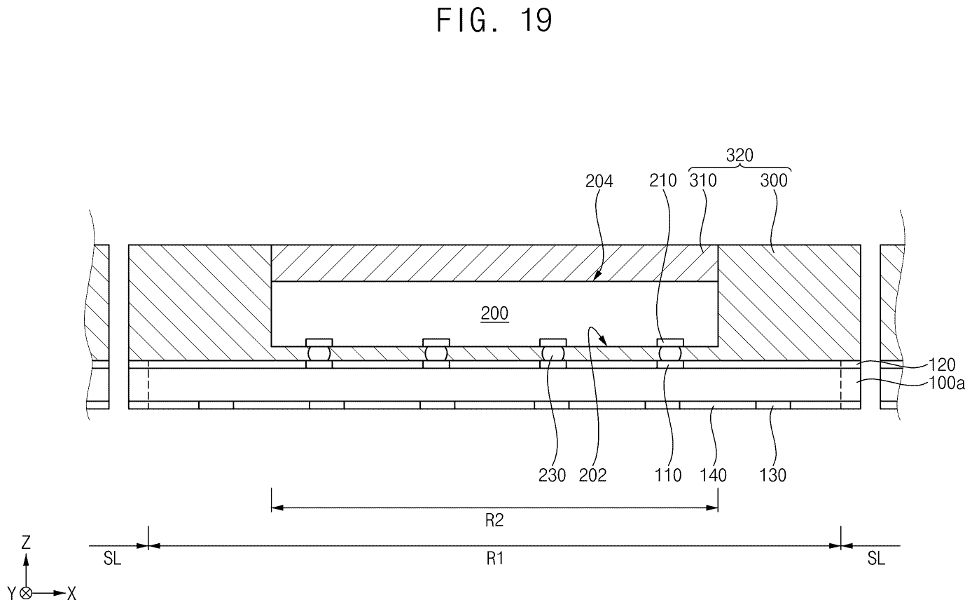

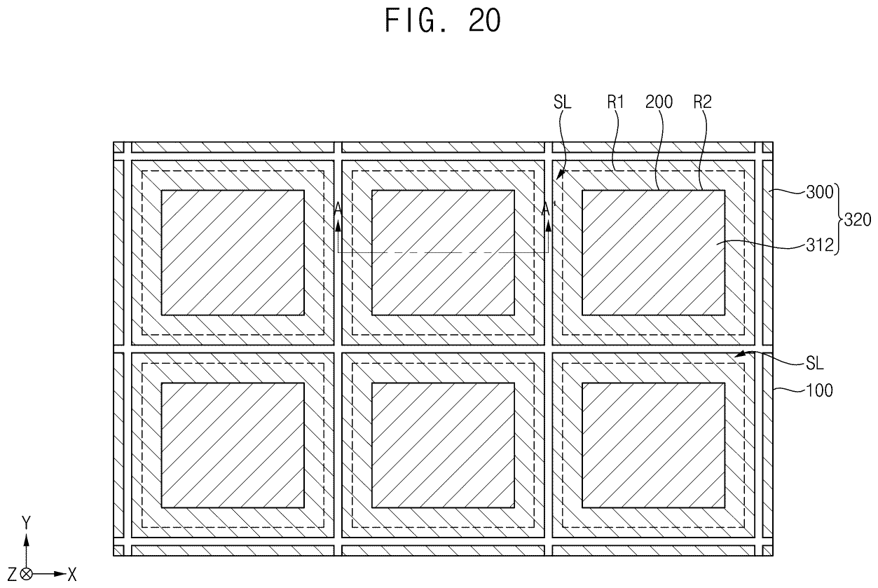

Referring to FIGS. 19 and 20, the sawing lane SL portion of the strip substrate 100 and the first molding member 300 on the sawing lane SL may be cut by the sawing process. When the sawing process is performed, the second molding member 310 may not be cut at all.

In example embodiments, the sawing process may include a laser sawing process or a blade sawing process.

For example, when the laser sawing process is performed, a laser irradiation unit may move along the sawing lane SL of the strip substrate 100, and the sawing laser from the laser irradiation unit may be irradiated to the sawing lane SL. For example, the sawing laser may include a CO₂ laser, an IR laser, or a green laser, etc. A width of the sawing laser may be smaller than a width of the sawing lane SL.

As shown in FIGS. 1 and 2, the package regions R1 of the strip substrate 100 may be separated by the sawing process, and thus the semiconductor package 10 in which the semiconductor chip 200 is mounted on the package substrate 100a may be manufactured.

In the laser sawing process, thermal energy may be generated during the sawing laser irradiation. When the hardness of the molding member for removing (to be removed) through the laser sawing process is high, time for applying the sawing laser to the sawing lane SL and the number of times the sawing laser reciprocates along the sawing lane SL may increase. Therefore, thermal damage may be inflicted to the semiconductor chip 200 formed on the strip substrate 100 during the sawing laser irradiation. For example, an increased number of reciprocating beams passing along the sawing lane SL may increase cumulative energy deposition, which may damage structures adjacent to the lane during irradiation. In particular, when the thermal conductivity of the molding member that is removed through the laser sawing process is high, excessive thermal energy may be applied to inside of (or transmitted into) the semiconductor chip 200 during the laser sawing process. Therefore, a defect in the semiconductor chip 200 may occur. However, in example embodiments, the first molding member 300 having lower thermal conductivity lower than the second molding member 310 and lower hardness than the second molding member 310 may be cut by the laser sawing process, and the second molding member 310 may not be cut. Therefore, defects in the semiconductor chip due to the thermal energy generated in the laser sawing process may be decreased.

In an example, the blade sawing process may be performed. When the hardness of the molding member for removing (to be removed) through the blade sawing process is high, significant wear of the blade may occur or a cutting failure may occur in the bleed sawing process. In addition, high currents may be generated between the blade and the molding member, which may cause the blade saw apparatus to stop operating or cause the blade saw apparatus to fail. However, in example embodiments, during the blade sawing process, the first molding member 300 having lower thermal conductivity than the second molding member 310 and lower hardness than the second molding member 310 may be cut, and the second molding member 310 may not be cut. Therefore, the wear of the blade and a defect of the molding member not being cut may be decreased in the blade sawing process.

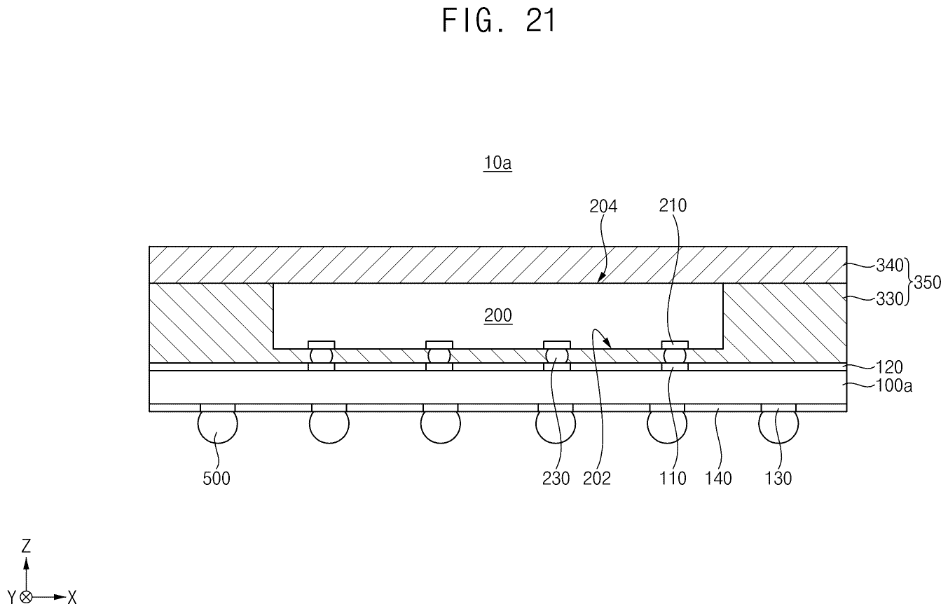

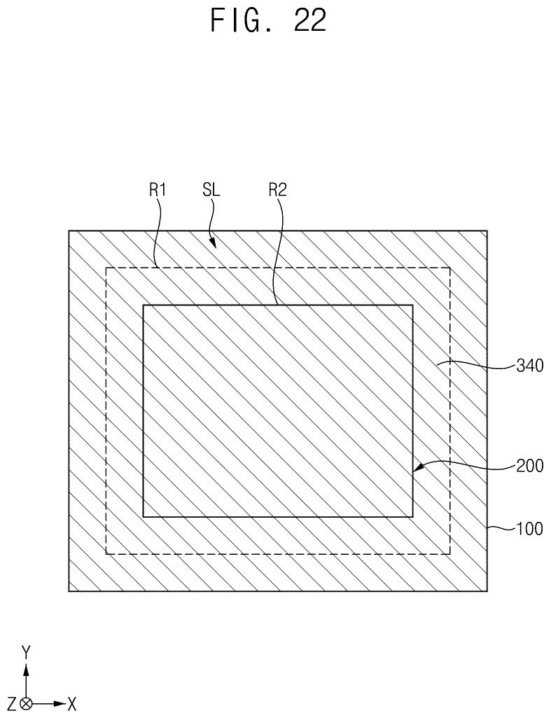

FIG. 21 is a cross-sectional view illustrating a semiconductor package according to example embodiments. FIG. 22 is a plan view illustrating a semiconductor package according to example embodiments.

Referring to FIGS. 21 and 22, the semiconductor package 10a may include a package substrate 100a, a semiconductor chip 200, a first molding member 330, and a second molding member 340. In addition, the semiconductor package 10a may further include external connection members 500.

The first molding member 330 may be placed on the package substrate 100a to cover sidewalls and a lower surface of the semiconductor chip 200. The first molding member 330 may contact the package substrate 100a.

The first molding member 330 may fill a gap between the package substrate 100a and the first surface of the semiconductor chip 200, and may cover an upper surface of the package substrate 100a and the sidewalls of the semiconductor chip 200.

An upper surface of the first molding member 330 and the second surface 204 of the semiconductor chip 200 may be substantially coplanar with each other. The upper surface of the first molding member 330 and the second surface 204 of the semiconductor chip 200 may be substantially flat. The first molding member 330 may not cover the second surface of the semiconductor chip 200. Therefore, the second surface 204 of the semiconductor chip 200 may be exposed by (or with respect to) the first molding member 330.

The first molding member 330 may include a material the same as the material of the first molding member described with reference to FIGS. 1 to 3. For example, the first molding member 330 may include the first epoxy mold compound (EMC) including the first filler 302. The first filler 302 (referred to FIG. 3) may have the first thermal conductivity and the first hardness.

In example embodiments, the first filler 302 may include a silicon-based filler or an aluminum-based filler. For example, the first filler 302 may include silica filler or an aluminum oxide filler.

The second molding member 340 may cover the upper surface of the first molding member 330 and the second surface 204 of the semiconductor chip 200. The second molding member 340 may contact the second surface 204 of the semiconductor chip 200 and the upper surface of the first molding member 330. The first molding member 330 may not be disposed on the second surface 204 of the semiconductor chip 200.

A boundary surface between the first molding member 330 and the second molding members 340 and the second surface 204 of the semiconductor chip 200 may be coplanar with each other. The upper surface of the second molding member 340 may be substantially flat.

The second molding member 340 may include a material the same as the material of the second molding member described with reference to FIGS. 1 to 4. The second molding member 340 may include the second epoxy mold compound (EMC) including the second filler 312 different from the first filler 302. The second filler 312 may have the second thermal conductivity different from the first thermal conductivity and the second hardness different from the first hardness. The second thermal conductivity may be higher than the first thermal conductivity, and the second hardness may be higher than the second hardness.

In example embodiments, the second filler 312 (referred to FIG. 4) may include a carbon-based filler. The second filler 312 may include, e.g., a diamond filler. The second filler 312 may have a polygonal shape of cross-section.

In some example embodiments, the second filler 312 may include a metal-based filler. The metal-based filler may be, e.g., a metal particle such as gold, silver (Ag), copper (Cu), or nickel (Ni).

An outer wall of the first molding member 330, an outer wall of the second molding member 340, and sidewalls of the package substrate 100a may extend in the vertical direction without a bent portion. The outer wall of the first molding member 330, the outer wall of the second molding member 340, and the sidewalls of the package substrate 100a may be disposed on a straight line in the vertical direction (or in a vertical cross sectional view). For example, the outer wall of the first molding member 330, the outer wall of the second molding member 340, and the sidewalls of the package substrate 100a may be substantially coplanar with (or be flush with or terminate in the same plane as) each other.

A molding member structure 350 including the first and second molding members 330 and 340 may seal the semiconductor chip 200. In the semiconductor package 10a, the second filler 312 included in the second molding member 340 may have the thermal conductivity higher than the thermal conductivity of the first filler 302 included in the first molding member 330, so that heat generated from the semiconductor chip 200 may be easily dissipated to an outside of the semiconductor package 10a. Therefore, a defect of the semiconductor package 10a due to the heat generated from the semiconductor chip 200 may be decreased.

Unlike example embodiments, when the semiconductor chip is molded only with the second molding member, only the second molding member having high hardness may be cut by the sawing process. Since a thickness of the second molding member for cutting may be thick, and defects of the semiconductor package occur in the sawing process or the sawing process of the second molding member may not be easy. However, in example embodiments, when the sawing process is performed, the second molding member 340 and the first molding member 330 may be sequentially cut. Since the molding member may include the first molding member 330 that can be easily cut, a thickness of the second molding member 340 for cutting may be decreased. Therefore, the molding member structure 350 including the second molding member 340 and the first molding member 330 may be easily sawed, and thus the semiconductor package may be easily manufactured.

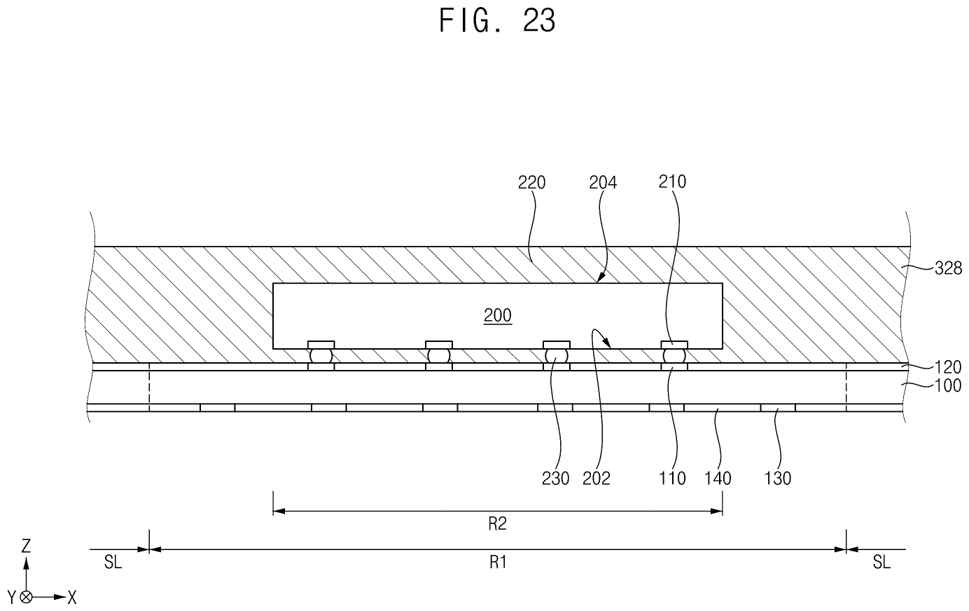

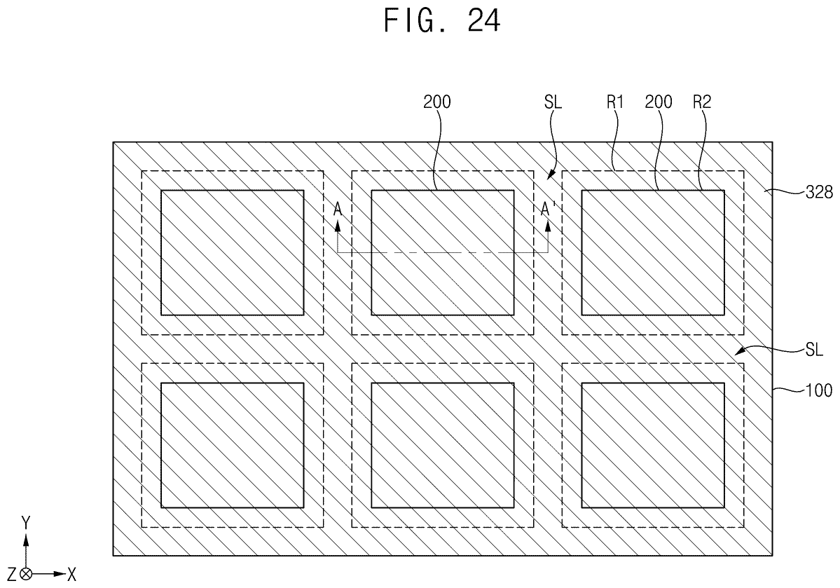

FIGS. 23 to 30 are cross-sectional views and plan views illustrating a method of manufacturing a semiconductor package according to example embodiments.

Referring to FIGS. 23 and 24, the processes described with reference to FIGS. 5 to 6 may be performed. Therefore, the semiconductor chip 200 may be mounted on each of the chip regions R2 of the strip substrate 100.

Thereafter, a preliminary first molding member 328 may be formed on the strip substrate 100 to cover the semiconductor chip 200. The preliminary first molding member 328 may include a material the same as the material of the preliminary first molding member described with reference to FIGS. 11 and 12. The preliminary first molding member 328 may cover sidewalls, a lower surface, and an upper surface of the semiconductor chip 200 on the strip substrate 100. The preliminary first molding member 328 may cover the sidewalls of the semiconductor chip 200 on the strip substrate 100, may fill a gap between the strip substrate 100 and the first surface of the semiconductor chip 200, and may cover the upper surface of the semiconductor chip 200. The upper surface of the preliminary first molding member 328 may be higher than the second surface 204 of the semiconductor chip 200. For example, the upper surface of the preliminary first molding member 328 may be spaced farther from the strip substrate 100 than the second surface 204 of the semiconductor chip 200.

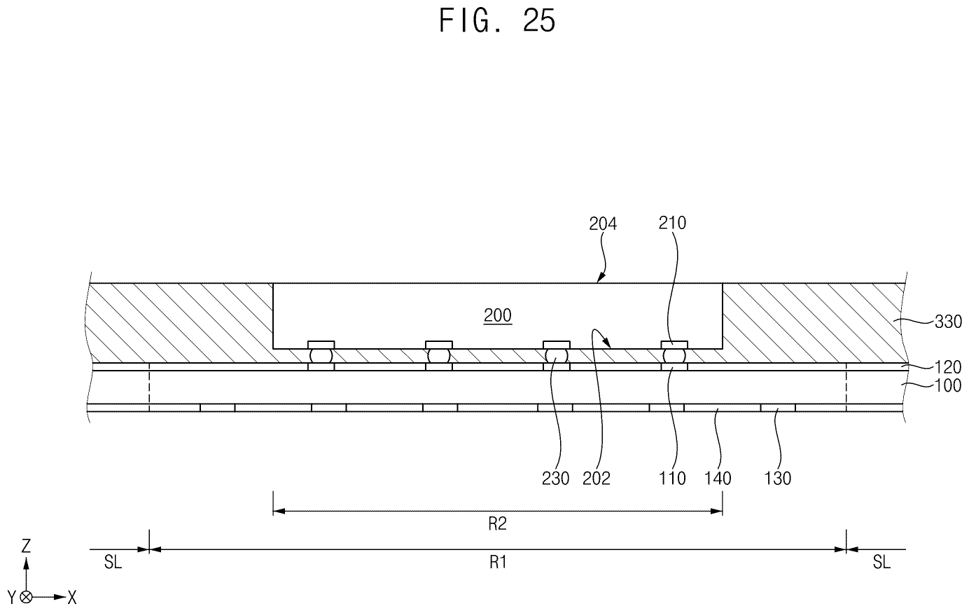

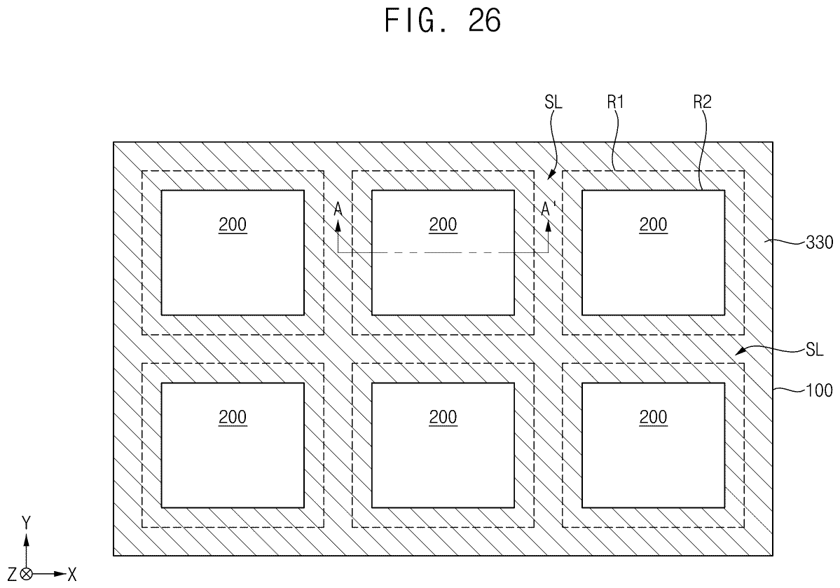

Referring to FIGS. 25 and 26, an upper portion of the preliminary first molding member 328 may be removed by a planarization process until the second surface 204 of the semiconductor chip 200 may be exposed to form the first molding member 330. For example, the remaining portion of the preliminary first molding member 328 may become the first molding member 330. The planarization process may include, e.g., a grinding process.

The upper surface of the first molding member 330 and the second surface 204 of the semiconductor chip 200 may be substantially coplanar with each other. The upper surface of the first molding member 330 and the second surface 204 of the semiconductor chip 200 may be substantially flat.

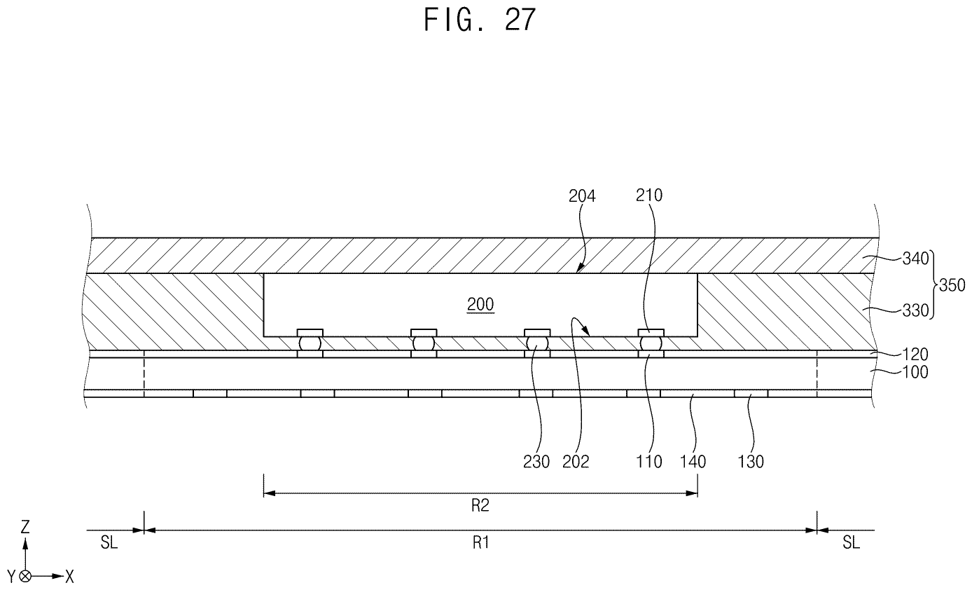

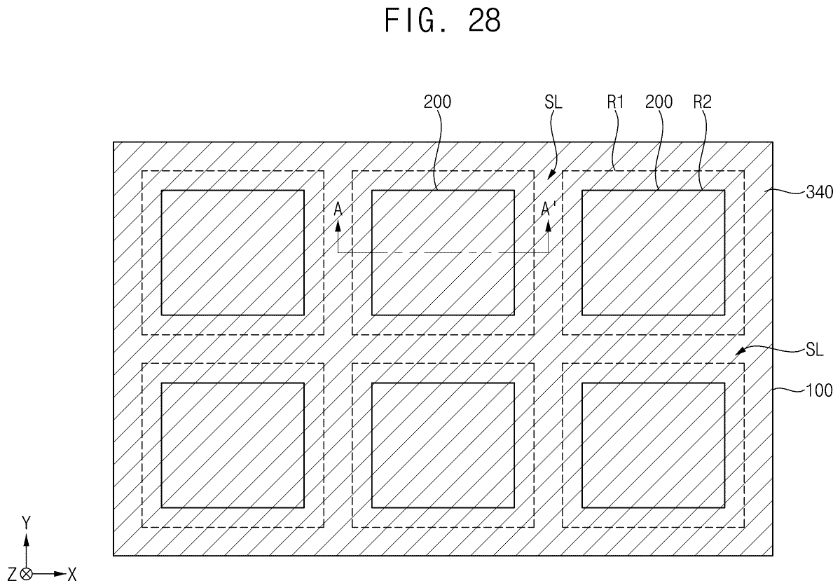

Referring to FIGS. 27 and 28, a second molding member 340 may be formed on the upper surface of the first molding member 330 and the upper surface of the semiconductor chip 200. Accordingly, a molding member structure 350 including the first and second molding members 330 and 340 may be formed on the strip substrate 100.

The second molding member 340 may include a material the same as the material of the second molding member described with reference to FIGS. 15 and 16.

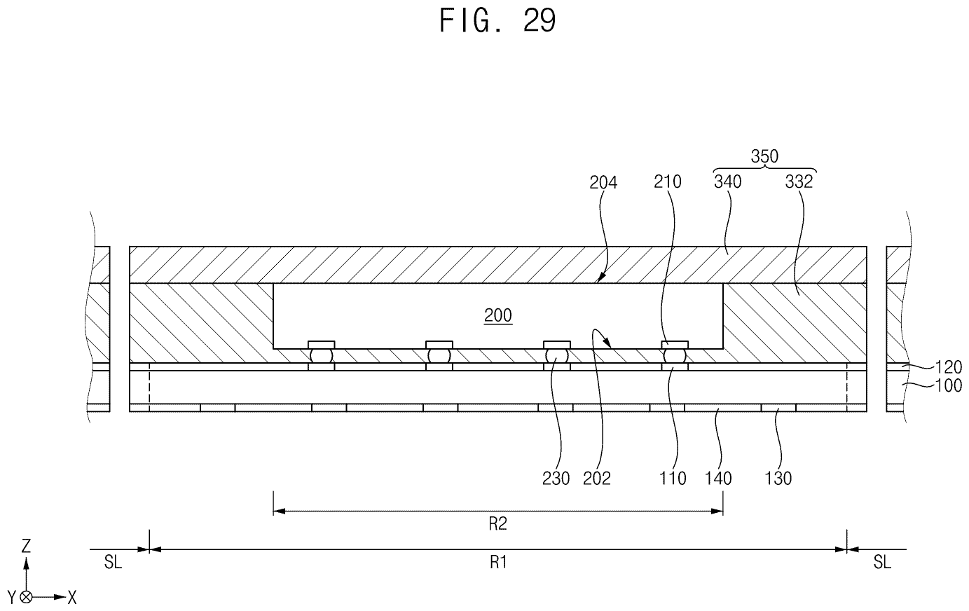

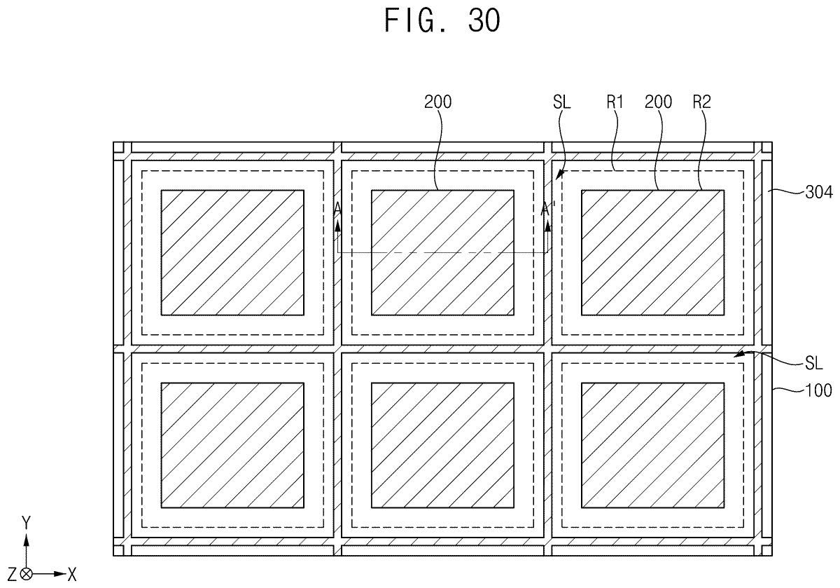

Referring to FIGS. 29 and 30, the sawing lane SL portion of the strip substrate 100 and the first molding member 330 and the second molding member 340 on the sawing lane SL may be cut by a sawing process. When the sawing process is performed, the second molding member 340 and the first molding member 330 having lower thermal conductivity and lower hardness than the second molding member 340 may be sequentially cut.

In example embodiments, the sawing process may include a laser sawing process or a blade sawing process.

The first molding member 330 has a relatively low hardness, and the semiconductor chip 200 may be sealed with the first and second molding members 330 and 340. Therefore, in the laser sawing process, the first and second molding members 330 and 340 may be cut more easily than in a case where the semiconductor chip is sealed only with the second molding member. Therefore, the heat generated in the laser sawing process may be decreased. Accordingly, a defect of the semiconductor chip 200 may be decreased.

For example, since the second molding member 340 and the first molding member 330 having lower thermal conductivity than the second molding member 340 and lower hardness than the second molding member 340 may be sequentially cut in the sawing process, blade wear and defects in which the molding member is not cut may be decreased as compared to the case where only the second molding member is cut.

As described above, the semiconductor package may include semiconductor devices such as logic devices or memory devices. The semiconductor package may include the logic devices such as a central processing unit CPU, MPU, an application processor AP, etc., volatile memory devices such as an SRAM device, a DRAM device, etc., and nonvolatile memory devices such as a flash memory device, a PRAM device, an MRAM device, an RRAM device, etc.

While the present inventive concepts have been shown and described with reference to example embodiments thereof, it will be understood by those of ordinary skill in the art that various changes in the example embodiments may be made without departing from the scope of the present inventive concepts.

What is claimed is:

1. A semiconductor package, comprising:
a package substrate;
a semiconductor chip mounted on the package substrate, the semiconductor chip including a first surface and a second surface opposite the first surface, wherein the first surface faces the package substrate;
a first molding compound covering sidewalls of the semiconductor chip, wherein the second surface of the semiconductor chip is exposed with respect to the first molding compound, and the first molding compound includes a first filler having a first thermal conductivity and a first hardness; and
a second molding compound contacting the second surface of the semiconductor chip and covering the second surface of the semiconductor chip,
wherein the second molding compound contacts a portion of the first molding compound, and
wherein the second molding compound includes a second filler having a second thermal conductivity different from the first thermal conductivity and a second hardness different from the first hardness.

2. The semiconductor package of claim 1, wherein the second thermal conductivity is greater than the first thermal conductivity, and the second hardness is greater than the first hardness.

3. The semiconductor package of claim 1, wherein the first filler includes a silicon-based filler or an aluminum-based filler, and the second filler includes a carbon-based filler.

4. The semiconductor package of claim 1, wherein the first filler and the second filler have different shapes of cross-section.

5. The semiconductor package of claim 4, wherein the first filler has a circular shape of cross-section, and the second filler has a polygonal shape of cross-section.

6. The semiconductor package of claim 1, wherein an upper surface of the first molding compound is spaced farther from the package substrate than the second surface of the semiconductor chip is, and
wherein the second molding compound contacts sidewalls of the first molding compound at a position spaced farther from the package substrate than the second surface of the semiconductor chip is.

7. The semiconductor package of claim 6, wherein the upper surface of the first molding compound and the upper surface of the second molding compound are coplanar with each other.

8. The semiconductor package of claim 1, wherein an upper surface of the first molding compound and the second surface of the semiconductor chip are coplanar with each other, and
wherein the second molding compound contacts the upper surface of the first molding compound.

9. The semiconductor package of claim 1, further comprising conductive bumps interposed between the package substrate and the semiconductor chip, and
wherein the semiconductor chip is mounted on the package substrate
wherein the conductive bumps as disposed between the semiconductor chip and the package substrate
wherein chip pads are formed on the first surface of the semiconductor chip, and
wherein the conductive bumps are in contact with the chip pads.

10. A semiconductor package, comprising:
a package substrate;
a semiconductor chip disposed on the package substrate, the semiconductor chip including a first surface and a second surface opposite the first surface, wherein the first surface of the semiconductor chip faces the package substrate;
conductive bumps interposed between the package substrate and the semiconductor chip;
a first molding compound:
disposed on the package substrate, wherein the second surface of the semiconductor chip is exposed with respect to the first molding compound,
covering at least sidewalls of the semiconductor chip, and
including a first epoxy molding compound including a first filler; and
a second molding compound contacting the entire second surface of the semiconductor chip, and including a second epoxy molding compound including a second filler different from the first filler.

11. The semiconductor package of claim 10, wherein the first filler has a first thermal conductivity and a first hardness, and the second filler has a second thermal conductivity greater than the first thermal conductivity and a second hardness greater than the first hardness.

12. The semiconductor package of claim 10, wherein the first filler includes a silicon-based filler or an aluminum-based filler, and the second filler includes a carbon-based filler.

13. The semiconductor package of claim 10, wherein the first filler and the second filler have different shapes of cross-section.

14. The semiconductor package of claim 10, wherein an upper surface of the first molding compound is spaced farther from the package substrate than the second surface of the semiconductor chip is, and
wherein the second molding compound contacts sidewalls of the first molding compound at a position spaced farther from the package substrate than the second surface of the semiconductor chip is.

15. The semiconductor package of claim 14, wherein the upper surface of the first molding compound and an upper surface of the second molding compound are coplanar with each other.

16. The semiconductor package of claim 14, wherein an outer wall of the first molding compound and sidewalls of the package substrate are aligned on a straight line in a vertical cross sectional view.

17. The semiconductor package of claim 10, wherein an upper surface of the first molding compound and the second surface of the semiconductor chip are coplanar with each other, and
wherein the second molding compound contacts the upper surface of the first molding compound.

18. The semiconductor package of claim 17, wherein an outer wall of the first molding compound, the outer wall of the second molding compound, and sidewalls of the package substrate are aligned on a straight line in a vertical cross sectional view.

19. A semiconductor package, comprising:
a package substrate;
a semiconductor chip mounted on the package substrate, the semiconductor chip including a first surface on which chip pads are formed and a second surface opposite the first surface, the first surface of the semiconductor chip facing the package substrate;
a first molding compound:
filling a gap between the package substrate and the first surface of the semiconductor chip,
covering sidewalls of the semiconductor chip and an upper surface of the package substrate, wherein the second surface of the semiconductor chip is exposed with respect to the first molding compound, and an upper surface of the first molding compound is spaced farther from the package substrate than the second surface of the semiconductor chip is, and
including a first filler having a first thermal conductivity; and
a second molding compound covering the second surface of the semiconductor chip and contacting the second surface of the semiconductor chip, the second molding compound including a second filler having a second thermal conductivity greater than the first thermal conductivity.

20. The semiconductor package of claim 19, wherein the first filler includes a silicon-based filler or an aluminum-based filler, and the second filler includes a carbon-based filler.
